(19) United States
(12) Patent Application Publication
(10) Pub. No.: US 2006/0143907 A1
(43) Pub. Date: Jul. 6, 2006

(54) Practical process for integrating circuits and components into nonrigid materials

(76) Inventors: Tuyetnhung Thi Pham, Saugus, MA (US); Eric Wilson Brown, Saugus, MA (US)

Correspondence Address: Tuyetnhung T. Pham, 110 Golden Hills Road, Saugus, MA, 01906-4004, US

(21) Appl. No.: 11/026,745

(22) Filed: Dec. 31, 2004

(51) Int. Cl. H05K 3/30; G01R 31/28

(52) U.S. Cl. 29/831; 29/846; 29/832; 29/593

(57) ABSTRACT

Discloses a method of incorporating electronic circuitry into flexible materials (including fabrics, textiles, leathers, vinyl, canvas, etc.) that allows for hand sewing, machine sewing, or embroidering, and incorporates both surface-mount and through-hole electrical components.

### BACKGROUND OF THE INVENTION

This invention provides a novel process of embedding electronic circuits (and portions of circuits) into nonrigid materials in a manner that lends itself well to automation and mass-production. It also addresses issues of heat and moisture in the finished product. It is applicable to medical devices; gear for sporting, gaming, camping, and hunting; wearable computers and electronics; portable radio, computing, and entertainment; children's toys, robotics, and numerous military applications.

The need to embed circuits into flexible materials is well-established in many fields and there has been some related work in the past few years. All of the prior art has limitations, however. Some restrict circuits to specially prepared fabric; some require specially prepared electrical components; some focus upon the concept of embedding circuits within fabric without providing a practical process for how such a thing should be done; some are constrained to complete circuits; some cannot be practically automated or mass produced; and virtually none take into account the standard requirements (especially testing) of the electronic circuit layout industry. This disclosed process addresses all of these limitations.

This disclosed process works well with standard, off-the-shelf electrical components and ordinary non-rigid materials like fabrics and leathers. It can be used for completely new designs or to convert an existing printed circuit board (PCB) design to a stitched circuit design, and it addresses all the issues of automation making it truly practical to mass-produce electronics on nonrigid materials of arbitrary size and shape.

### SUMMARY OF THE INVENTION

This invention describes a method of incorporating electronic circuits (or portions of circuits) into non-rigid materials. It is a flexible method that takes into account all the best practices of both the electronics and sewing industries. It incorporates testing throughout but does not require it at any particular stage. It addresses the needs of not just prototypes and short-runs, but also mass production and assembly lines.

### BRIEF DESCRIPTION OF THE DRAWINGS

Other features, advantages, and uses of the invention will occur to those skilled in the art from the following detailed description taken in conjunction with the accompanying drawings.

FIG. 1 is a flowchart of the overall process in accordance with the invention.

FIG. 2 is a flowchart of the hand-sewing subprocess referenced in FIG. 1.

FIG. 3 is a flowchart of the machine-sewing subprocess referenced in FIG. 1.

FIG. 4 is a flowchart of the embroidery subprocess referenced in FIG. 1.

FIG. 5 is a diagram showing how a standard sewing machine works. The normal operation is prior art; however, this case shows conductive thread loaded into the bobbin.

FIG. 6 is a diagram showing the detail of a trace being formed by a standard embroidery stitch utilizing conductive thread. For clarity a small amount of space is shown separating each thread; it should be noted however that in reality each thread touches its neighbors.

FIG. 7 is a diagram of a machine's standard zigzag stitch with non-conductive thread loaded in the top and bobbin being used to encapsulate a trace. For clarity the zigzags are shown some distance apart; in reality they can be virtually adjacent.

FIG. 8 is a diagram of a wire being couched to a nonrigid material via a standard sewing machine's zigzag stitch capability with non-conductive thread loaded both in top and bobbin. Couching has been used for decorative purposes for millennia; special prior art couching feet (albeit designed with different intent) exist to facilitate this portion of the described process.

FIG. 9 is a diagram showing the details of traces and pads being created by a sewing machine using conductive thread. Pad variations for both surface-mount and through-hole components are pictured. The spacing between stitches has been increased for illustration purposes; in reality they can be adjacent.

FIG. 10 is a diagram showing how the embroidered trace can be encapsulated and insulated via a second embroidery pass. Details of the encapsulated traces and embroidered pads are also provided. The spacing between stitches has been exaggerated for diagram clarity. In reality they are

FIG. 11 is a diagram showing how adhesive may be automatically applied while sewing. The design of the roller itself is prior art, but this usage is novel.

FIG. 12 is a diagram showing conductive adhesive compound being selectively spread onto a stitched circuit utilizing a standard aluminum mask. This prior art PCB technique can be applied without change as part of this new process.

FIG. 13 is a diagram detailing a large mounted component. Non-conductive threads are shown holding it in place in addition to its soldered connection to the embroidered pads. Also, the spacing between the stitches has been increased for diagram clarity.

FIG. 14 is a diagram showing how multiple layer circuits can be created via this process; this capability makes the transfer of multiple layer PCB designs seamless.

FIG. 15 is a diagram showing a protective lamination layer being applied.

FIG. 16 is a diagram showing an example use case of how circuitry can be embedded within a pair of boots. It illustrates both the finished product and the pattern.

FIG. 17 is a diagram showing an example use case of how circuitry can be embedded within a parachute. It illustrates both the finished product and the pattern for a single panel.

FIG. 18 is a diagram showing an example use case of how circuitry can be embedded into a virtual reality control device. It illustrates the pattern for each side of the device.

### DETAILED DESCRIPTION OF THE INVENTION

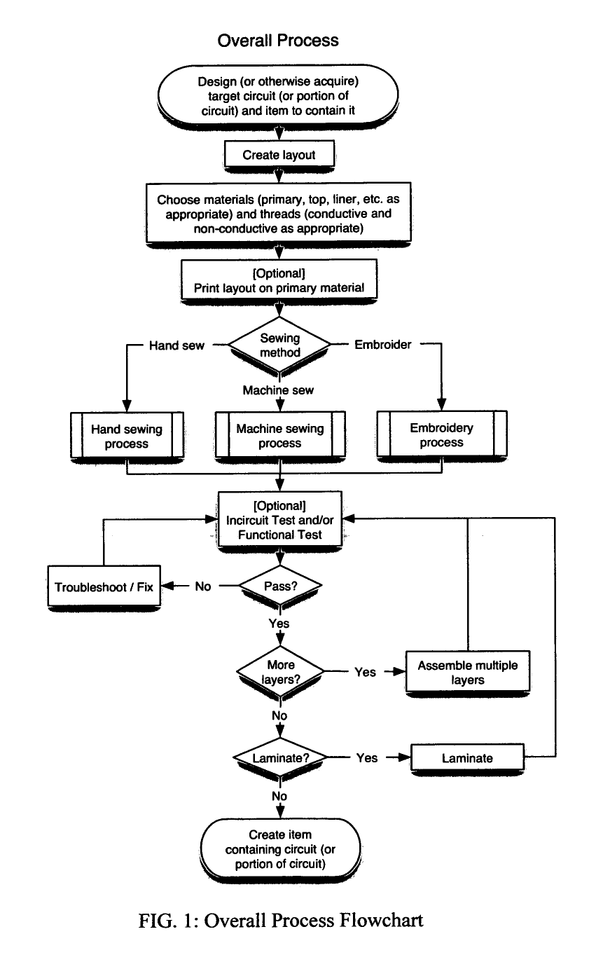

Referring to FIG. 1, a manufacturing process for incorporating circuitry into nonrigid materials in accordance with the invention includes the following steps:

Deciding upon both a circuit (or portion of circuit) and an item to contain it. In addition to new designs, anything that can be expressed electronically with a combination of PCBs can be readily converted for use with this process. The containing item can be virtually anything assembled from nonrigid materials like textiles, fabrics, leathers, synthetics, or composites.

The electronics layout must be created. This is analogous to generating a trace for a PCB, and existing PCB designs can be readily converted. This method is far more flexible than PCB design, though, and because shapes and sizes may be arbitrary it is easier to separate components to better dissipate heat and reduce cross talk. Likewise a pattern for the containing item must be laid out. These two operations may be performed in parallel and can be done using software or by hand.

Appropriate materials must be chosen for the design. Material selection includes not only the primary material to hold the electronics, but also potential decorative materials, liners, pudding, and threads (conductive and non-conductive as needed).

The electronics layout can optionally be printed upon the primary material.

A sewing method must be chosen. Hand sewing and machine sewing are most appropriate for short runs or prototypes. Embroidery is most appropriate for mass production. Each of these three options has its own diagram and will be discussed in detail later.

Once the electronics have been applied to the primary material, it is suggested that industry-standard incircuit tests and/or functional tests be performed. Failed tests result in a typical cycle of troubleshooting and fixing and retesting.

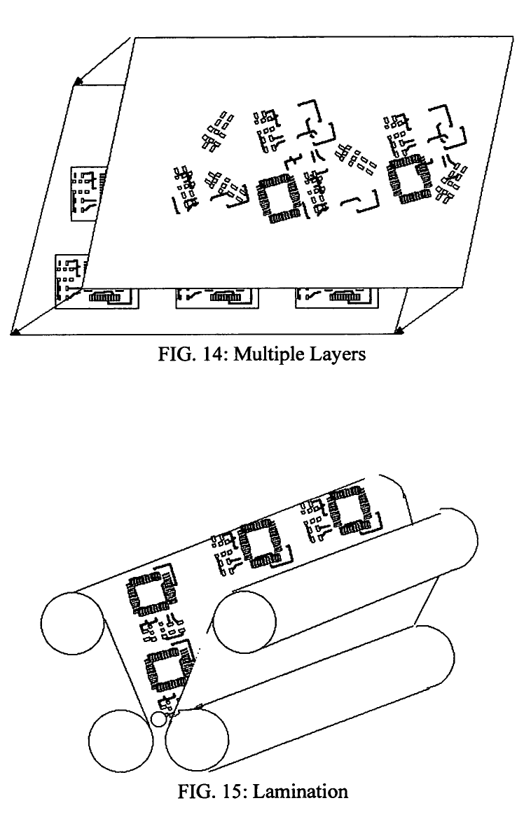

If multiple layers are required for the design, individual layers (each made in accordance with the described process) must be assembled together. FIG. 14 shows multiple layers being combined.

If lamination is desired, it can be applied. Lamination can provide protection for the electronic components against moisture and sweat. FIG. 15 shows an example of lamination.

Multiple layers can be individually tested and laminated as required by the overall design. Ultimately a final as-built test is suggested to verify proper operation of the electrical portion.

The last stage is the final assembly of the item containing the circuit (or portion of circuit).

There are three possible sewing methods. Each has its own advantages and disadvantages, and it is possible to utilize all three in a single design, especially if multiple layers are employed.

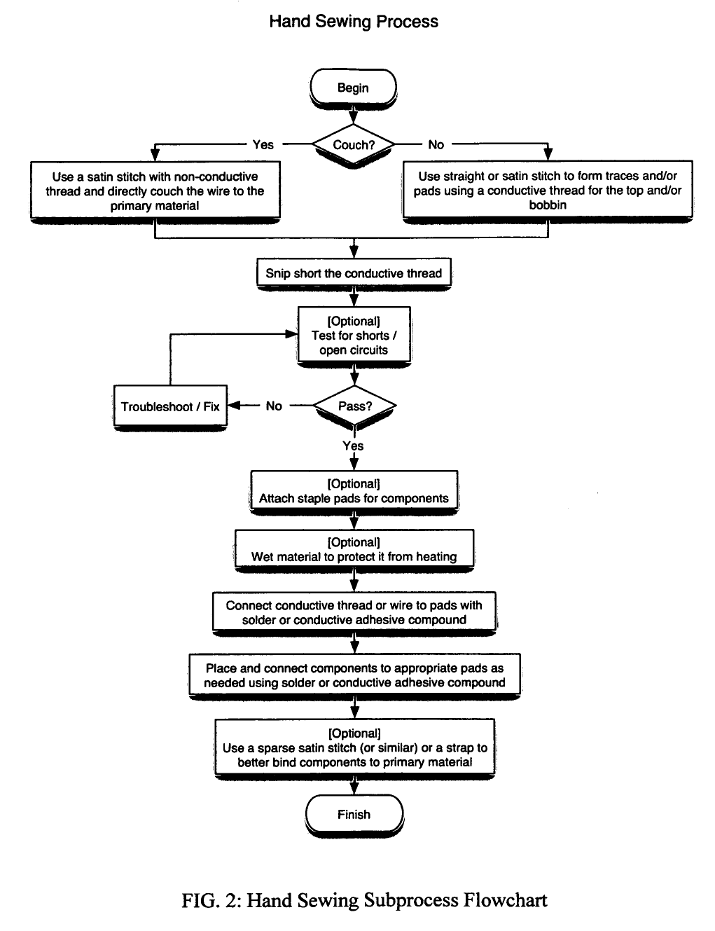

Referring to FIG. 2, a manufacturing subprocess for hand sewing circuitry into nonrigid materials in accordance with the invention includes the following steps:

It must first be decided whether conductive materials, wires, or cables are to be couched onto the primary material; or conductive threads sewn into the primary material.

If conductive material is to be couched, it can be done so via any the prior art methods of hand couching decorative material to fabric (e.g. a satin stitch).

If conductive thread is to be sewn into the primary material, traces and/or pads via a simple straight stitch, satin stitch or other similar method. A satin stitch using non-conductive thread can be applied afterwards to encapsulate the conductive thread. Note that different colored threads may be used to make the overall layout easier to understand.

The excess conductive threads should be snipped to prevent shorts.

Testing may be performed to check for open circuits or shorts resulting from the sewing process. Hand work is somewhat susceptible to both open circuits and shorts. If problems are found, the normal troubleshooting, fixing, and retesting cycle commences.

If pads were not stitched with conductive threads, staple pads must be attached for the components. Staple pads with holes are used for through-hole components, and staple pads without holes are used for surface-mount components.

The primary material may be wet to protect it from processing heat (like from soldering).

The conductive threads or wires must be connected to the pads. This can be achieved via either soldering or conductive adhesive compound.

The components must be placed onto the appropriate pads and connected via either solder or conductive adhesive compound. FIG. 12 shows an example of applying conductive adhesive compound to pads in preparation for component placement.

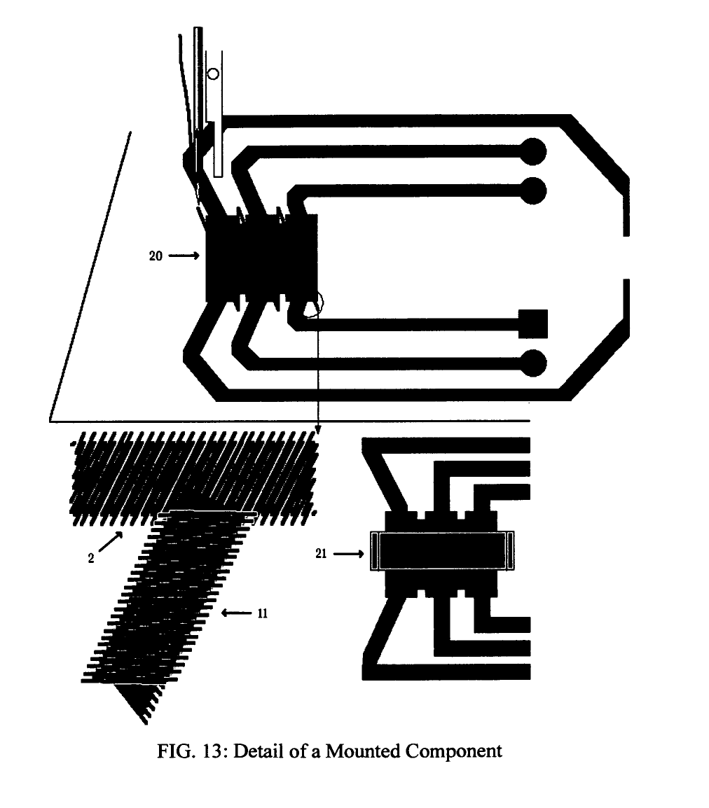

A sparse satin stitch (or similar hand technique) can be used to optionally reinforce the physical connections of the components to the primary material. Straps may be used in lieu of thread. FIG. 13 shows a mounted component reinforced with stitches (20), a mounted component reinforced with a strap (21), and detail of both the encapsulated trace (11) and the pad where it joins the trace (2).

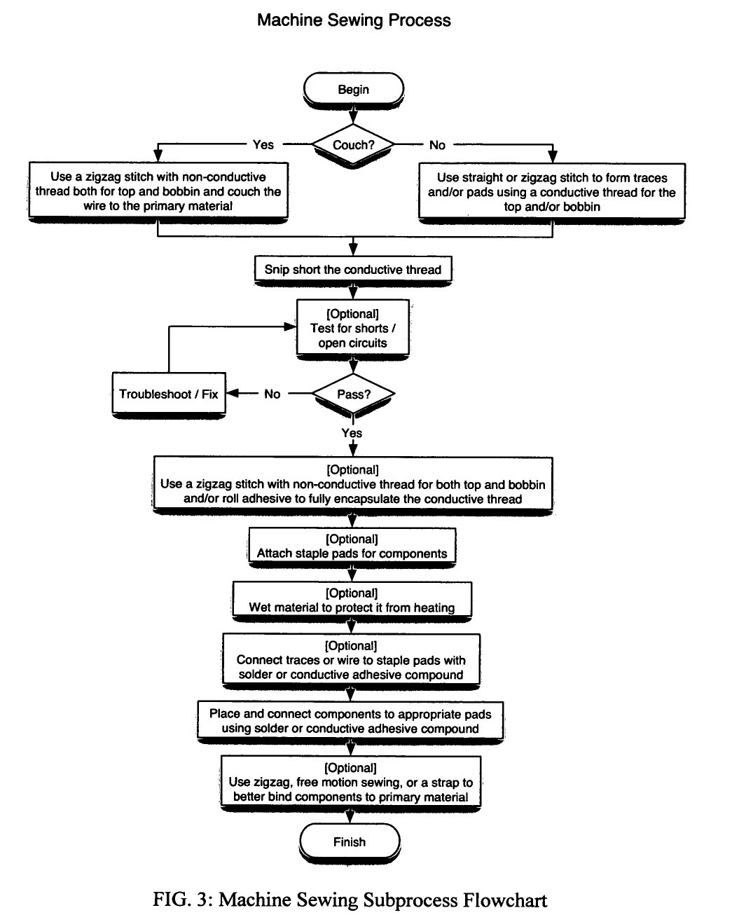

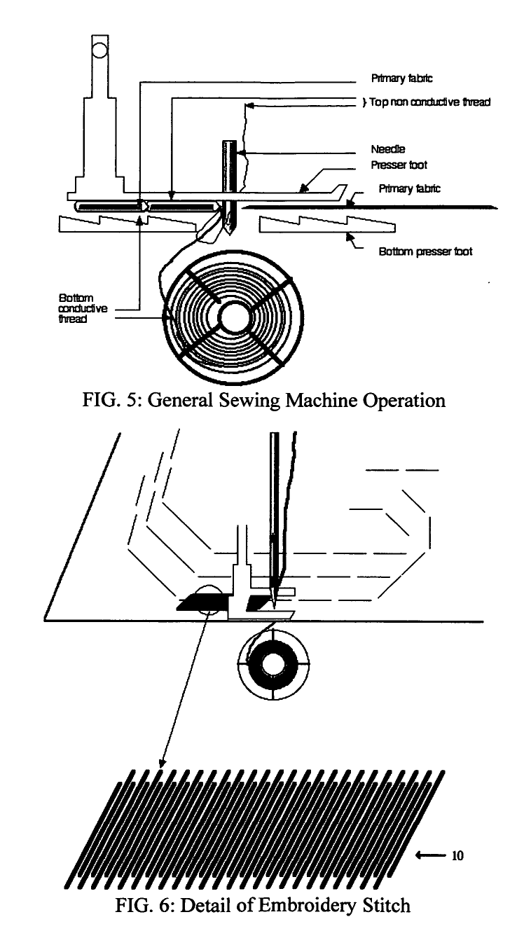

Referring to FIG. 3, a manufacturing subprocess for machine sewing circuitry into nonrigid materials in accordance with the invention includes the following steps (see FIG. 5 for a detailed example of basic sewing machine operation; while this particular example illustrates conductive thread in the bobbin and non-conductive thread in the upper thread dispenser, the same general operation holds regardless of the specifics):

It must first be decided whether conductive materials, wires, or cables are to be couched onto the primary material; or conductive threads sewn into the primary material.

If conductive material is to be couched, it can be done so via any the prior art methods of machine couching decorative material to fabric (e.g. a zigzag stitch utilizing a couching foot). FIG. 8 shows an example of a wire being machine couched to the primary material.

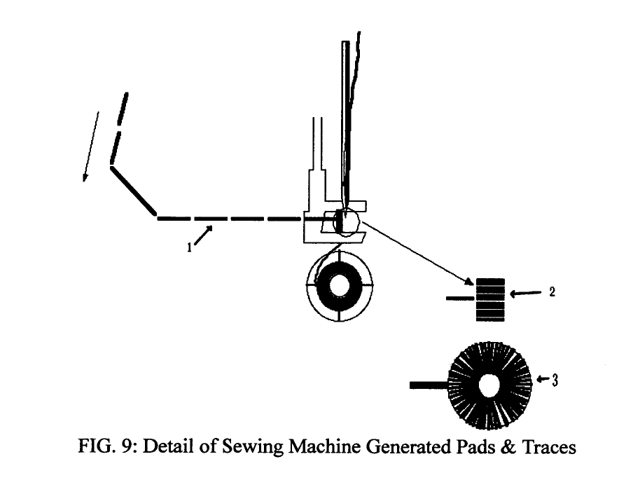

If conductive thread is to be sewn into the primary material, traces and/or pads can be created using zigzag stitches. Conductive thread can be loaded into the upper thread dispenser, the bobbin, or both as needed. FIG. 9 shows in detail how traces (1) and both circular (2) and rectangular (3) pads can be generated.

The excess conductive threads should be snipped to prevent shorts.

Testing may be performed to check for open circuits or shorts resulting from the sewing process. Machine work is susceptible to both open circuits and shorts at this stage, and fixes are difficult after encapsulation has been performed. If problems are found, the normal troubleshooting, fixing, and retesting cycle commences.

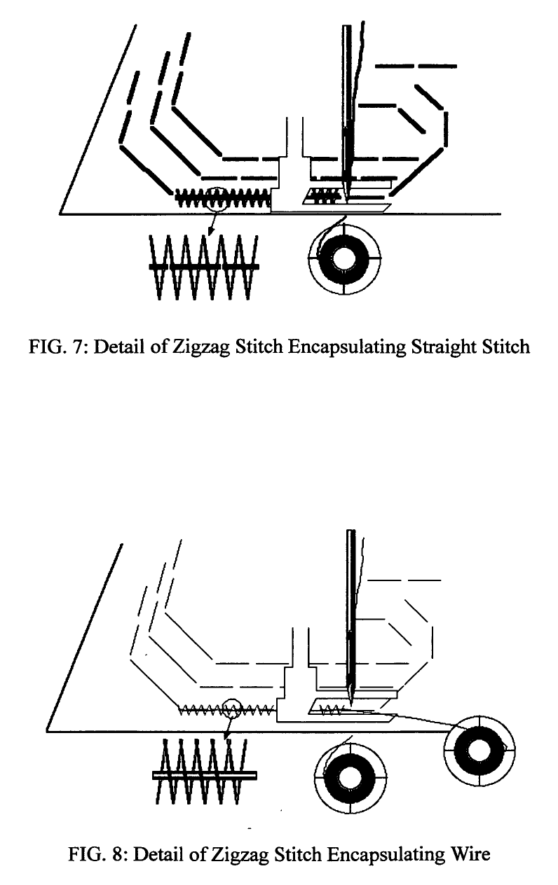

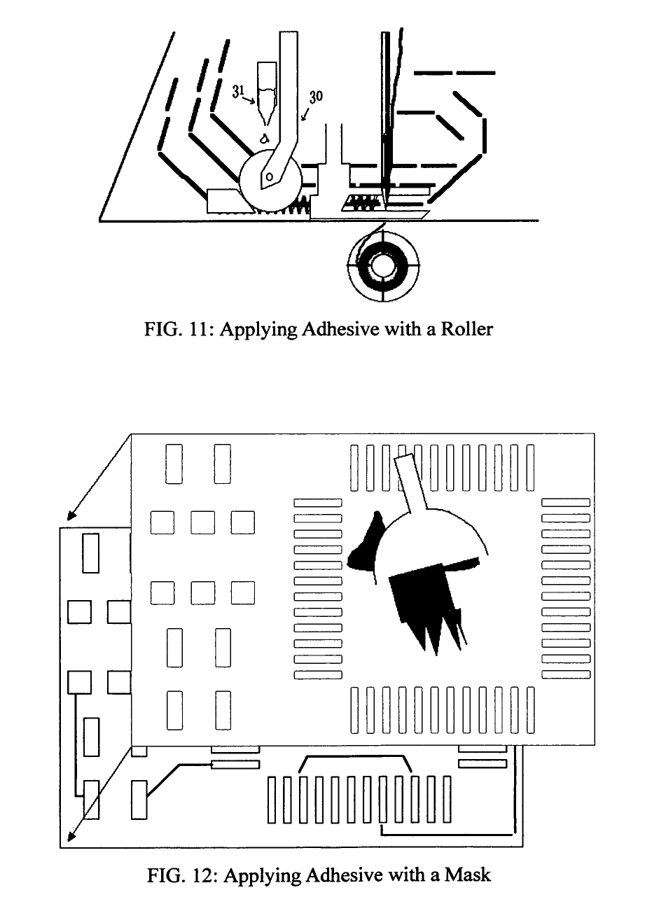

A zigzag stitch with non-conductive thread in both the upper thread dispenser and bobbin may be used to fully encapsulate the conductive thread. Adhesive may be additionally applied to further isolate and protect the conductive thread. FIG. 11 depicts this being done with a roller (30) and adhesive dispenser (31). FIG. 7 shows an example of a zigzag stitch encapsulating a straight stitch; this particular configuration utilizes non-conductive thread in both the bobbin and the upper thread dispenser. Note that different colored threads may be used for encapsulation to make the overall layout easier to understand.

If pads were not stitched with conductive threads, staple pads must be attached for the components. Staple pads with holes are used for through-hole components, and staple pads without holes are used for surface-mount components.

The primary material may be wet to protect it from processing heat (like from soldering).

If staple pads are being used, the conductive threads or wires must be connected to them. This can be achieved via either soldering or conductive adhesive compound.

The components must be placed onto the appropriate pads and connected via either solder or conductive adhesive compound. FIG. 12 shows an example of applying conductive adhesive compound to pads in preparation for component placement.

The physical connections of the components to the primary material may be optionally reinforced with a zigzag stitch, free motion sewing, sparse satin stitch, or similar machine or hand technique. Straps may be used in lieu of thread. FIG. 13 shows a mounted component reinforced with stitches (20), a mounted component reinforced with a strap (21), and detail of both the encapsulated trace (11) and the pad where it joins the trace (2).

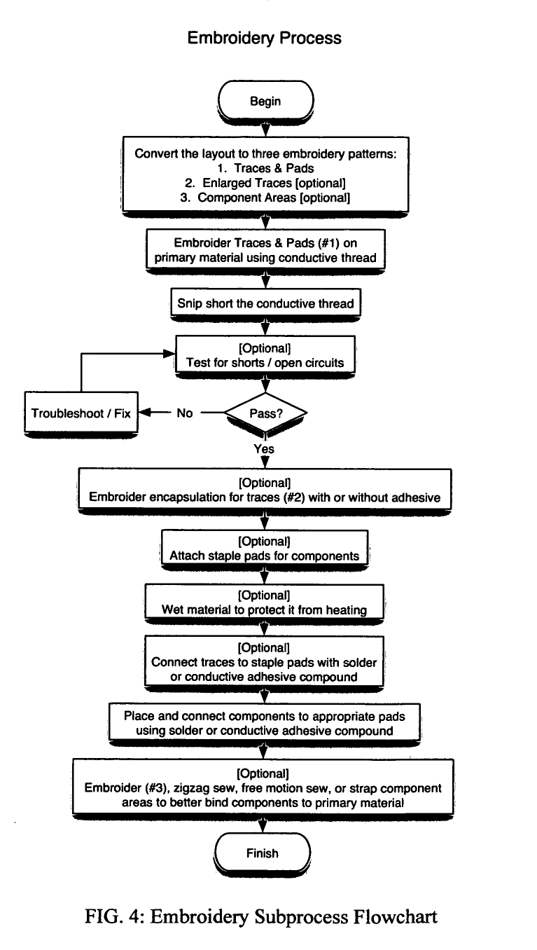

Referring to FIG. 4, a manufacturing subprocess for embroidering circuitry into nonrigid materials in accordance with the invention includes the following steps:

The electrical layout must be converted to at least one embroidery pattern encompassing the traces and pads. It may optionally be trivially converted to an additional enlarged traces pattern for automated trace encapsulation and a component areas pattern for automated physical component connection reinforcement.

The traces and pads must be embroidered onto the primary material using conductive thread. FIG. 6 shows the detail of a trace being embroidered.

The excess conductive threads should be snipped to prevent shorts.

Testing may be performed to check for open circuits or shorts resulting from the sewing process. Embroidery is somewhat susceptible to both open circuits and shorts at this stage, and fixes are difficult after encapsulation has been performed. If problems are found, the normal troubleshooting, fixing, and retesting cycle commences.

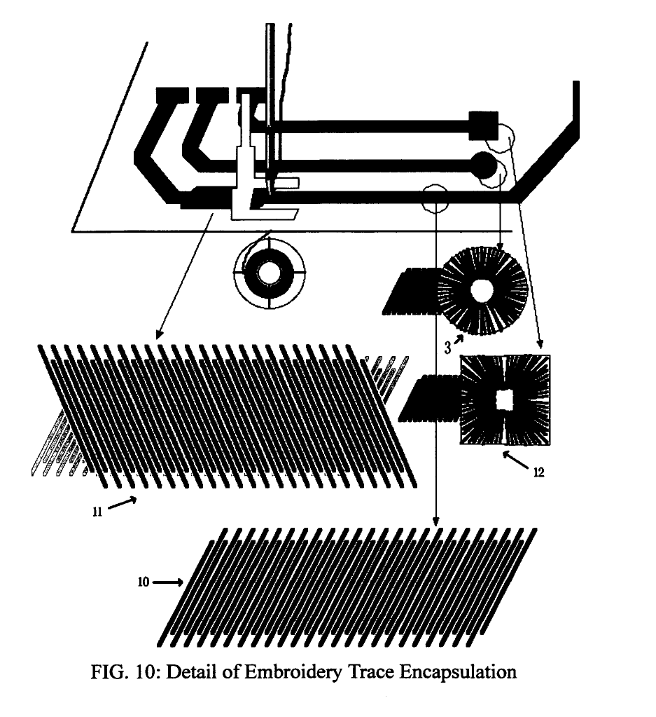

If an enlarged traces embroidery pattern was created, the traces can be encapsulated by embroidering this pattern using non-conductive thread. FIG. 10 shows a trace (10) encapsulated by non-conductive thread (11), and the detail of an embroidered through-hole rectangular pad (12) and an embroidered through-hole circular pad (3). Adhesive may be additionally applied to further isolate and protect the traces. FIG. 11 depicts this being done with a roller (30) and adhesive dispenser (31). Note that different colored threads may be used for encapsulation to make the overall layout easier to understand.

If pads were not embroidered, staple pads must be attached for the components. Staple pads with holes are used for through-hole components, and staple pads without holes are used for surface-mount components.

The primary material may be wet to protect it from processing heat (like from soldering).

If staple pads are being used, the traces must be connected to them. This can be achieved via either soldering or conductive adhesive compound.

The components must be placed onto the appropriate pads and connected via either solder or conductive adhesive compound. FIG. 12 shows an example of applying conductive adhesive compound to pads in preparation for component placement.

The physical connections of the components to the primary material may be optionally reinforced utilizing the component areas embroidery pattern if one was created. Otherwise they may be reinforced with a zigzag stitch, free motion sewing, sparse satin stitch, or similar machine or hand technique. Straps may be used in lieu of thread. FIG. 13 shows a mounted component reinforced with stitches (20), a mounted component reinforced with a strap (21), and detail of both the encapsulated trace (11) and the pad where it joins the trace (2).

Many fields can benefit from this process, and the types of items that it can be applied to are almost limitless.

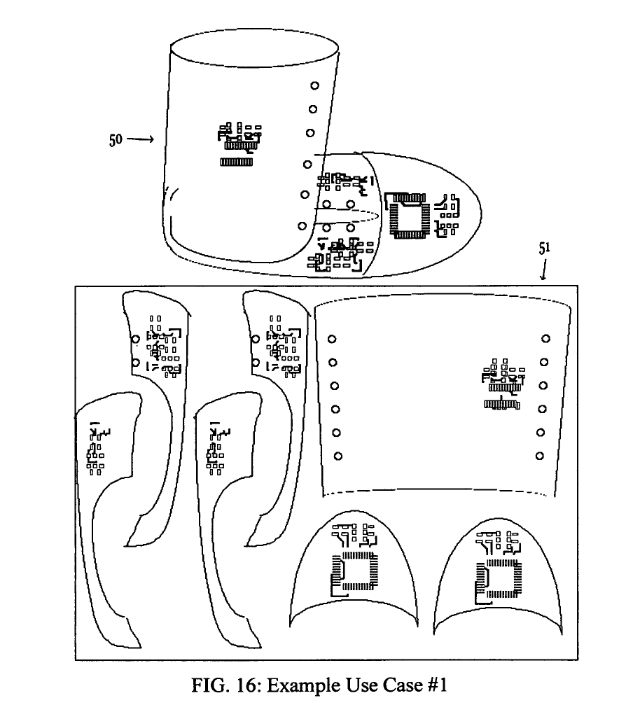

FIG. 16 shows circuitry embedded in a boot. The boot fully assembled (50) will have electronics distributed throughout its three-dimensional surface. Obviously additional layers or decoration could be applied to make the final item more sartorially appealing. The pattern of the boot in leather (51) provides a simple two-dimensional surface that can be repeated on a roll for easy mass production. The purpose of the electronics will vary based upon desired application—it could be a homing signal for a child's boots, a GPS for a soldier's boots, or whatever is desired.

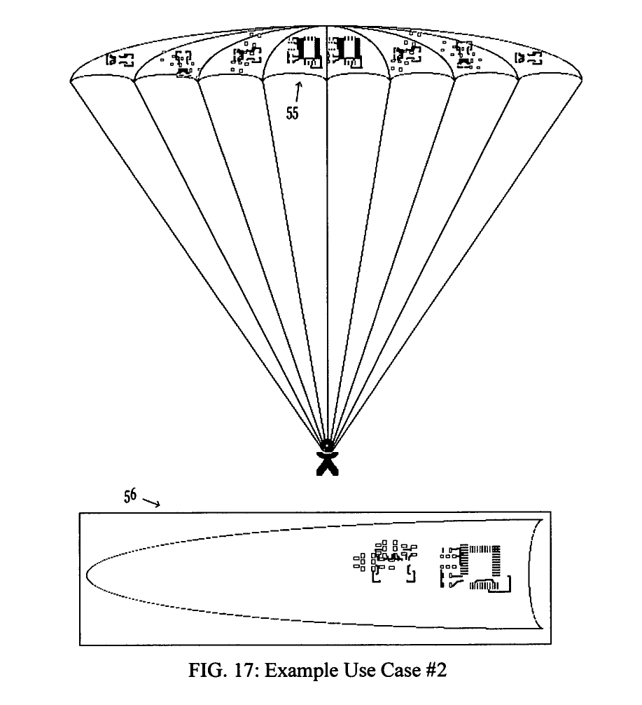

FIG. 17 shows circuitry embedded in a parachute. The parachute fully assembled (55) will have electronics widely distributed throughout its surface making heat almost a non-issue. Each panel (56) will hold a portion of the overall circuit. The purpose of the electronics will vary based upon desired application—it could be for something as simple as a light generator for night air shows or something as complicated as a radio control relay to make remote controlled parachute landings more accurate.

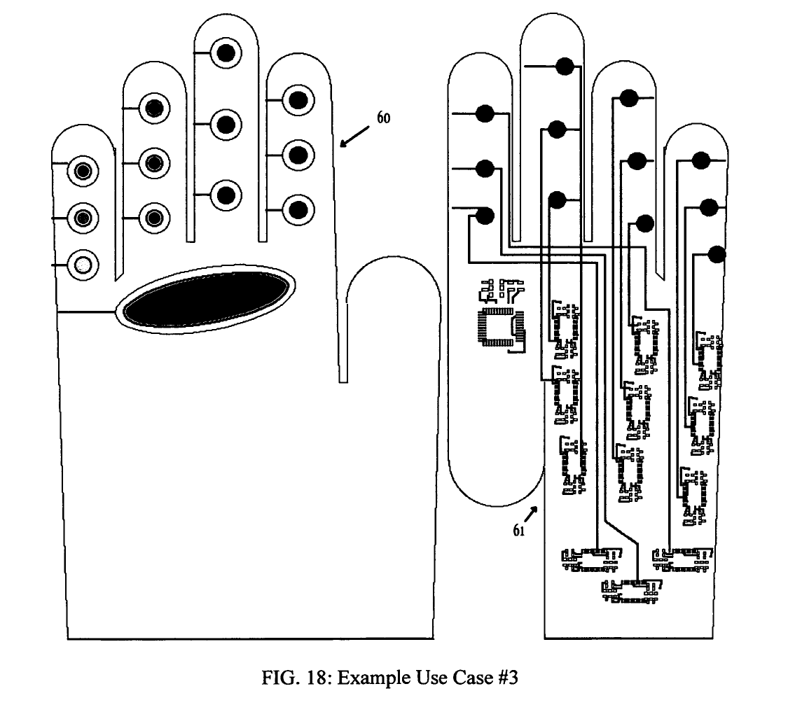

FIG. 18 shows circuitry embedded in a virtual reality control device meant to be worn as a glove. One side of the glove (60) is dedicated to sensors while another (61) contains interface circuitry.

From the above description it is noted that the invention has the following advantages:

The process works with existing electrical components, nonrigid materials, and (often) assembly tools.

The process supports the best practices of both the electronics and sewing industries.

The process is not limited to simple circuits or any particular category of circuits.

The process is not limited to any particular category of nonrigid materials.

The process supports both new designs and straightforward conversion from existing PCB designs.

The process supports mass production.

It is to be understood, however, that while numerous advantages of this invention have been presented in the foregoing description along with details of the structure and function of the invention, that the disclosure is illustrative only, and changes may be made in detail (especially in matters of shape, size and arrangement of parts) within the principles of the invention to the full extent indicated by the broad general meaning of the terms in which the appended claims are expressed.

What is claimed is as follows:

1. A manufacturing method for incorporating electronic circuits (or portions of circuits) into nonrigid materials comprising (at minimum) the following steps:
the working of conductive pathways onto or into the nonrigid material;
the mounting of electrical components onto the nonrigid material;
testing the resulting circuit (or portion of circuit).

2. The article of claim 1 in which the conductive pathways consist of wires or cables.

3. The article of claim 1 in which the conductive pathways consist of threads.

4. The article of claim 1 in which the electrical components are surface-mount components.

5. The article of claim 1 in which the electrical components are through-hole components.

6. The article of claim 1 in which the electrical components are attached via staples.

7. The article of claim 1 in which the electrical components are attached via stitched pads.

8. The article of claim 1 in which the electrical components are further secured to the nonrigid material with threads or straps.

9. The article of claim 1 in which the electrical components are attached or further secured to the nonrigid material with conductive adhesive compound.

10. The article of claim 1 in which the electrical components are attached or further secured to the nonrigid material with solder.

11. The article of claim 1 in which the nonrigid material is a textile.

12. The article of claim 1 in which the nonrigid material is leather or suede.

13. The article of claim 1 in which the nonrigid material is synthetic.

14. The article of claim 1 in which the nonrigid material is a composite or laminate.

15. The article of claim 1 in which the encapsulating threads are color-coded.

16. The article of claim 1 further including the step of protecting the nonrigid material against processing heat by wetting.

17. The article of claim 1 in which the conductive pathways are couched onto the nonrigid material via hand sewing.

18. The article of claim 1 in which the conductive pathways are sewn into the nonrigid material via hand sewing.

19. The article of claim 1 in which the conductive pathways are couched onto the nonrigid material via machine sewing.

20. The article of claim 1 in which the conductive pathways are sewn into the nonrigid material via machine sewing.

21. The article of claim 1 in which the conductive pathways are embroidered onto the nonrigid material.

22. The article of claim 1 further including the encapsulation of the conductive pathways using nonconductive threads.

23. The article of claim 1 further including the encapsulation of the conductive pathways using an adhesive.

24. The article of claim 1 further including the protective lamination of the nonrigid material after processing.

25. The article of claim 1 applied to multiple layers designed to work together.

26. The article of claim 1 further including testing for shorts and open circuits mid process.

27. The article of claim 1 further including as-built incircuit testing.

28. The article of claim 1 further including as-built functional testing.

29. The article of claim 1 applied to short-runs and prototypes.

30. The article of claim 1 applied to mass production.
